(19) United States
(12) Patent Application Publication
(10) Pub. No.: US 2025/0081353 A1
(43) Pub. Date: Mar. 6, 2025

(54) WIRING BOARD AND LAMINATED WIRING BOARD

(71) Applicant: SHINKO ELECTRIC INDUSTRIES CO., LTD., Nagano-shi (JP)

(72) Inventor: Yoshihiro Kobayashi, Nagano (JP)

(21) Appl. No.: 18/819,479

(22) Filed: Aug. 29, 2024

(30) Foreign Application Priority Data
Sep. 1, 2023 (JP) 2023-142412

(51) Int. Cl. H05K 1/18; H05K 1/11

(52) U.S. Cl. CPC H05K 1/186; H05K 1/112; H05K 2201/10378

(57) ABSTRACT

A wiring board includes a first wiring structure and a second wiring structure. The first wiring structure includes a mounting surface for a semiconductor element and a back surface on an opposite side of the mounting surface. The second wiring structure is formed on the back surface of the first wiring structure. The second wiring structure includes a reinforcing insulating layer, a cavity, an electronic component, and a filled resin layer. The reinforcing insulating layer is formed on the back surface of the first wiring structure. The cavity is formed by cutting off the reinforcing insulating layer in a direction toward the back surface of the first wiring structure. The electronic component is arranged in the cavity. The filled resin layer is filled in the cavity and covers the electronic component.

### CROSS-REFERENCE TO RELATED APPLICATION

This application is based upon and claims the benefit of priority of the prior Japanese Patent Application No. 2023-142412, filed on Sep. 1, 2023, the entire contents of which are incorporated herein by reference.

### FIELD

The embodiment discussed herein is related to a wiring board, a laminated wiring board, and a wiring board manufacturing method.

### BACKGROUND

Conventionally, for example, a laminated wiring board is known, in which a relay board that includes fine wiring is laminated on a main board. In the laminated wiring board as described above, in some cases, a semiconductor element is mounted on the relay board and an electronic component, such as a capacitor, is mounted around the relay board on the main board, for example. The electronic component that is mounted on the main board has a function to reduce noise that occurs from the semiconductor element that is mounted on the relay board.

Patent Literature 1: Japanese Laid-open Patent Publication No. 2001-144207

However, in the laminated wiring board as described above, there is a problem in that the noise from the semiconductor element spreads. Specifically, the semiconductor element that is mounted on the relay board and the electronic component that is mounted on the main board are connected to each other via wiring on the relay board and wiring on the main board, so that a length of wiring between the semiconductor element and the electronic component increases, which leads to an increase in an inductance of the wiring. As a result, the noise from the semiconductor element is not fully reduced in the electronic component, but may spread around the semiconductor element.

### SUMMARY

According to an aspect of an embodiment, a wiring board includes a first wiring structure that includes a mounting surface for a semiconductor element and a back surface on an opposite side of the mounting surface; and a second wiring structure that is formed on the back surface of the first wiring structure, wherein the second wiring structure includes a reinforcing insulating layer that is formed on the back surface of the first wiring structure, a cavity that is formed by cutting off the reinforcing insulating layer in a direction toward the back surface of the first wiring structure; an electronic component that is arranged in the cavity; and a filled resin layer that is filled in the cavity and covers the electronic component.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a structure of a board according to one embodiment;

FIG. 2 is a diagram illustrating a configuration of a first wiring board according to one embodiment;

FIG. 3 is a flowchart illustrating a method of manufacturing the first wiring board according to one embodiment;

FIG. 4 is a diagram illustrating a specific example of a glass support;

FIG. 5 is a diagram illustrating a specific example of a seed layer formation process;

FIG. 6 is a diagram illustrating a specific example of a resist layer formation process;

FIG. 7 is a diagram illustrating a specific example of a resist layer formation process;

FIG. 8 is a diagram illustrating a specific example of a resist layer removal process;

FIG. 9 is a diagram illustrating a specific example of a seed layer removal process;

FIG. 10 is a diagram illustrating a specific example of an insulating layer formation process;

FIG. 11 is a diagram illustrating a specific example of a seed layer formation process;

FIG. 12 is a diagram illustrating a specific example of a resist layer formation process;

FIG. 13 is a diagram illustrating a specific example of an electrolytic copper plating process;

FIG. 14 is a diagram illustrating a specific example of a resist layer removal process;

FIG. 15 is a diagram illustrating a specific example of a seed layer removal process;

FIG. 16 is a diagram illustrating a specific example of a solder adding process;

FIG. 17 is a diagram illustrating a specific example of a bonding layer formation process;

FIG. 18 is a flowchart illustrating a method of manufacturing the board according to one embodiment;

FIG. 19 is a diagram illustrating a specific example of a first wiring board mounting process;

FIG. 20 is a diagram illustrating a specific example of a glass support release process;

FIG. 21 is a diagram illustrating a configuration example of a semiconductor device;

FIG. 22 is a flowchart illustrating a method of forming a wiring structure according to one embodiment;

FIG. 23 is a diagram illustrating a specific example of a reinforcing insulating layer formation process;

FIG. 24 is a diagram illustrating a specific example of a via hole formation process;

FIG. 25 is a diagram illustrating a specific example of a seed layer formation process;

FIG. 26 is a diagram illustrating a specific example of a resist layer formation process;

FIG. 27 is a diagram illustrating a specific example of an electrolytic copper plating process;

FIG. 28 is a diagram illustrating a specific example of a resist layer removal process;

FIG. 29 is a diagram illustrating a specific example of a seed layer removal process;

FIG. 30 is a diagram illustrating a specific example of a cavity formation process;

FIG. 31 is a diagram illustrating a specific example of an electronic component arrangement process;

FIG. 32 is a diagram illustrating a specific example of an electronic component embedding process;

FIG. 33 is a diagram illustrating a specific example of a via hole formation process;

FIG. 34 is a diagram illustrating a configuration of a first wiring board according to a first modification of one embodiment;

FIG. 35 is a diagram illustrating a specific example of a cavity formation process;

FIG. 36 is a diagram illustrating a specific example of an electronic component arrangement process;

FIG. 37 is a diagram illustrating a configuration of a first wiring board according to a second modification of one embodiment;

FIG. 38 is a diagram illustrating a configuration of a first wiring board according to a third modification of one embodiment;

FIG. 39 is a diagram illustrating a specific example of a cavity formation process;

FIG. 40 is a diagram illustrating a specific example of an electronic component arrangement process;

FIG. 41 is a diagram illustrating a configuration of a first wiring board according to a fourth modification of one embodiment;

FIG. 42 is a diagram illustrating a specific example of a recessed portion formation process; and

FIG. 43 is a diagram illustrating a specific example of an electronic component arrangement process.

### DESCRIPTION OF EMBODIMENT

Embodiments of a wiring board, a laminated wiring board, and a wiring board manufacturing method disclosed in the present application will be described in detail below based on the drawings. The disclosed technology is not limited by the embodiments below.

### Embodiment

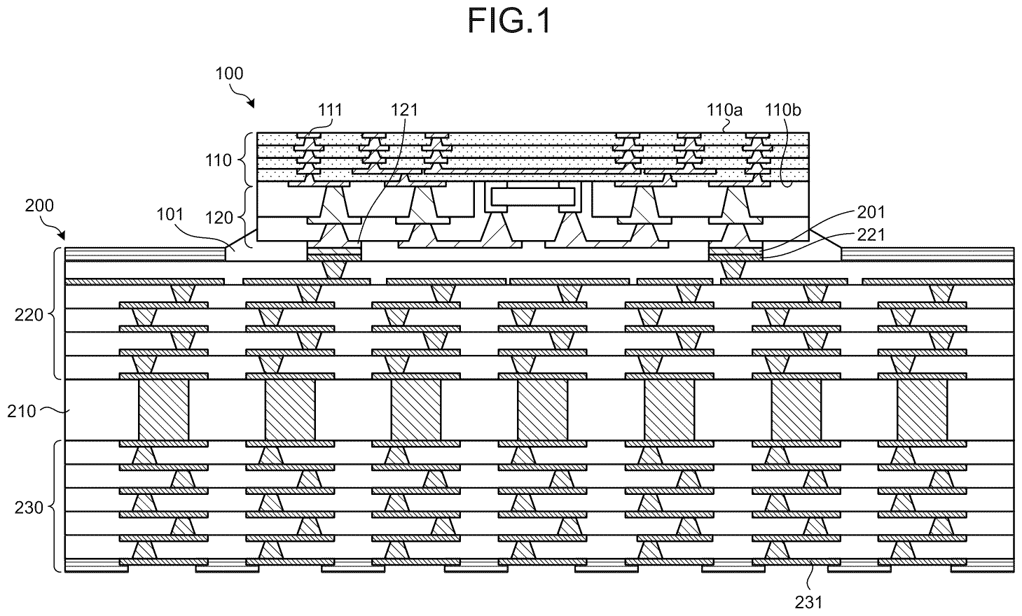

FIG. 1 is a diagram illustrating a structure of a board according to one embodiment. FIG. 1 schematically illustrates a cross section of the board according to one embodiment. The board illustrated in FIG. 1 is a laminated wiring board in which a first wiring board 100 is laminated on a second wiring board 200. In the description below, it is assumed that a direction extending from the second wiring board 200 to the first wiring board 100 in FIG. 1 indicates an upper side, and a direction extending from the first wiring board 100 to the second wiring board 200 indicates a lower side. However, the first wiring board 100 and the second wiring board 200 may be manufactured and used in, for example, an upside-down manner and may be manufactured and used in an arbitrary posture.

The first wiring board 100 is a relay board that includes a first wiring structure 110 in which a plurality of thin film layers are laminated and a second wiring structure 120 that serves as a base layer. An electrode pad 111 is formed on an upper surface 110a of the first wiring structure 110. The electrode pad 111 is made of, for example, a conductor, such as copper, and serves as a connection terminal when a semiconductor element is bonded to the first wiring board 100. Specifically, when the semiconductor element is bonded to the first wiring board 100, the semiconductor element is mounted on the upper surface 110a of the first wiring structure 110, and the electrode pad 111 and an electrode of the semiconductor element are bonded together by a solder. Further, an electrode pad 121 is formed on a lower surface of the second wiring structure 120. The electrode pad 121 is made of, for example, a conductor, such as copper, and serves as a connection terminal when the first wiring board 100 is bonded to the second wiring board 200. Furthermore, the electrode pad 121 is connected to wiring of the first wiring structure 110 via a wiring layer and a via inside the second wiring structure 120

The second wiring board 200 is a main board that includes a core layer 210, a build-up layer 220 that is laminated on the upper surface of the core layer 210, and a build-up layer 230 that is laminated on a lower surface of the core layer 210. An electrode pad 221 is formed on an upper surface of the build-up layer 220, and an electrode pad 231 is formed on a lower surface of the build-up layer 230. The electrode pad 221 is made of, for example, a conductor, such as copper, and serves as a connection terminal when the second wiring board 200 is bonded to the first wiring board 100. The electrode pad 231 is made of, for example, a conductor, such as copper, and serves as a connection terminal when the second wiring board 200 is bonded to an external component, such as a mother board. Further, wiring that electrically connects the electrode pad 221 and the electrode pad 231 is formed inside the core layer 210, inside the build-up layer 220, and inside the build-up layer 230.

The first wiring board 100 is mounted on the second wiring board 200. Specifically, the electrode pad 121 that serves as the connection terminal of the first wiring board 100 and the electrode pad 221 that serves as a connection terminal of the second wiring board 200 are bonded together by a solder 201. Further, a bonding layer 101 is formed between a lower surface of the first wiring board 100 (that is, the lower surface of the second wiring structure 120) and an upper surface of the second wiring board 200. The bonding layer 101 bonds the first wiring board 100 and the second wiring board 200 together in a state of covering a part of a side surface of the first wiring board 100. For example, insulating resin such as epoxy resin and polyimide resin is used as the bonding layer 101.

The first wiring board 100 and the second wiring board 200 that are bonded together by the bonding layer 101 and the solder 201 as described above are manufactured separately. The first wiring board 100 is manufacture on, for example, a support that is made of glass.

Specifically, the first wiring board 100 is manufactured by forming, on a glass support, the first wiring structure 110 in a state in which the upper surface 110a of the first wiring structure 110 is oriented toward the glass support, and laminating the second wiring structure 120 on a lower surface 110b of the first wiring structure 110. Then, the first wiring board 100 that is manufactured on the glass support and the second wiring board 200 are bonded together by the bonding layer 101 and the solder 201, and the glass support is separated from the first wiring board 100.

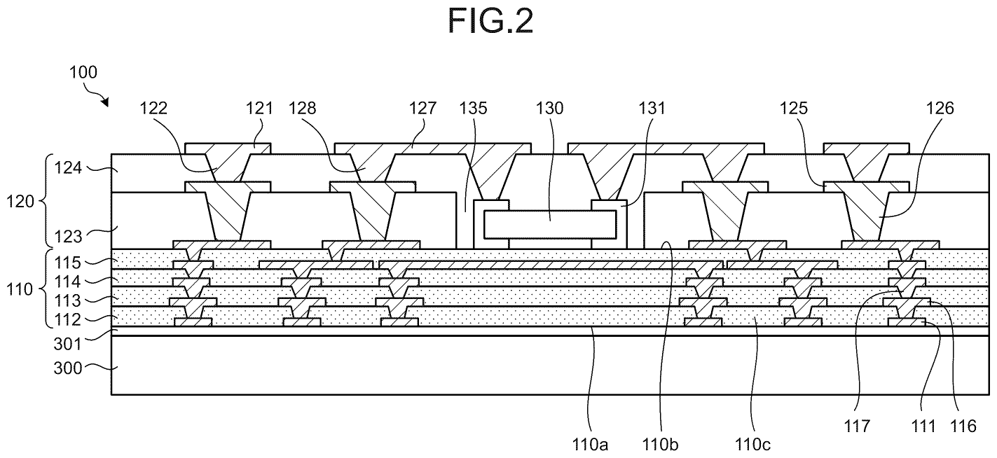

A configuration of an intermediate structure that is formed in a process of manufacturing the first wiring board 100 will be described below with reference to FIG. 2. FIG. 2 is a diagram illustrating a configuration of the first wiring board 100 according to one embodiment. An intermediate structure of the first wiring board 100 illustrated in FIG. 2 includes a glass support 300, the first wiring structure 110 that is formed on an upper side of the glass support 300, and the second wiring structure 120 that is laminated on the lower surface 110b of the first wiring structure 110. The first wiring structure 110 and the second wiring structure 120 are formed on the glass support 300 in an upside-down manner. Further, an electronic component 130 is embedded in the second wiring structure 120.

The glass support 300 is a support that has a flat upper surface, and a release layer 301 is formed on the upper surface. As the release layer 301, for example, an adhesive material of a silicone type or an acrylic type. By separating the glass support 300 from the release layer 301, the first wiring board 100 is obtained. The glass support 300 is separated from the release layer 301 after the first wiring board 100 that is manufactured on the glass support 300 and the second wiring board 200 are bonded together by the bonding layer 101 and the solder 201, for example. Meanwhile, it may be possible to use a different support other than the glass support 300, and it may be possible to use metal, silicon, ceramic, or the like as a material of the different support.

The first wiring structure 110 is a structure that includes a first thin film layer 112, a second thin film layer 113, a third thin film layer 114, and a fourth thin film layer 115 and that has a thickness of, for example, about 30 to 50 micrometers (μm). In this example, it is assumed that the first wiring structure 110 is formed by laminating four thin film layers on an upper surface of the glass support 300, but the number of the thin film layers laminated on the upper surface of the glass support 300 need not always four. Each of the first thin film layer 112 to the fourth thin film layer 115 is a thin film layer that is configured by forming a wiring layer 116 that includes fine wiring on an insulating layer 110c. The wiring layers 116 of the first thin film layer 112 to the fourth thin film layer 115 are connected to one another via a via 117 that penetrates through the insulating layer 110c. The via 117 is formed in a truncated cone shape in which a diameter at the side of the electrode pad 111 is smaller than a diameter at the side of the electrode pad 121.

The insulating layer 110c of each of the first thin film layer 112 to the fourth thin film layer 115 is formed by using, for example, photosensitive insulating resin. For example, photosensitive insulating resin such as epoxy resin and polyimide resin may be used as the insulating layer 110c. When a fine wiring layer 116 is formed on an upper side of each of the insulating layers 110c, a resist is formed on an upper surface of the insulating layer 110c and then patterning and electrolytic copper plating are performed.

An electrode pad 111 is embedded in the first thin film layer 112 that is a lowermost layer. The electrode pad 111 is made of, for example, a conductor, such as copper, and is used as a connection terminal when an semiconductor element is bonded to the first wiring board 100. A surface (lower surface) of the first thin film layer 112 located at the side of the upper surface of the glass support 300 forms the upper surface 110a of the first wiring structure 110 that serves as a mounting surface of the semiconductor element, and the electrode pad 111 is exposed from the first thin film layer 112 on the upper surface 110a of the first wiring structure 110. The electrode pad 111 is connected to the wiring layer 116 of the second thin film layer 113 via the via 117 that penetrates through the insulating layer 110c of the first thin film layer 112.

The second wiring structure 120 is a structure that includes a reinforcing insulating layer 123 and a filled resin layer 124 and that has a thickness of, for example, about 50 to 100 μm. The reinforcing insulating layer 123 is formed by impregnating insulating resin with a reinforcing member, such as a glass fiber. By including the reinforcing member in the reinforcing insulating layer 123, rigidity of the second wiring structure 120 increases as compared to rigidity of the first wiring structure 110, so that strength of the first wiring board 100 increases. The insulating resin that is impregnated with the reinforcing insulating layer 123 is, for example, resin, such as epoxy resin or polyimide resin, which is cured by thermal curing. A wiring layer 125 is formed on the surface of the reinforcing insulating layer 123. The wiring layer 125 is connected to wiring of the first wiring structure 110 via a via 126 that penetrates through the reinforcing insulating layer 123. The via 126 is formed in a truncated cone shape in which a diameter at the side of the electrode pad 111 is smaller than a diameter at the side of the electrode pad 121. The electronic component 130 is embedded in the reinforcing insulating layer 123. For example, an electronic component other than a capacitor, such as an inductor and a semiconductor element may be used as the electronic component 130. A cavity for housing the electronic component 130 is formed in the reinforcing insulating layer 123.

The filled resin layer 124 is a layer that is formed, in an electronic component embedding process (to be described later), so as to be continued with filling resin 135 that is filled in the cavity. The electrode pad 121 and wiring 127 are formed on surface of the filled resin layer 124. The electrode pad 121 is made of, for example, a conductor, such as copper, and serves as a connection terminal when the first wiring board 100 is bonded to the second wiring board 200. Wiring 127 is made of, for example, a conductor, such as copper, and serves as transmission wiring for transmitting an input-output signal of the electronic component 130. Vias 122 and 128 are formed in the filled resin layer 124 after the electronic component embedding process, and one of the electrode pad 121 and the wiring 127 on the surface of the filled resin layer 124 is connected to one of the wiring layer 125 on the surface of the reinforcing insulating layer 123 and an electrode 131 of the electronic component 130. The vias 122 and 128 are formed in a truncated cone shape in which a diameter at the side of the electrode pad 111 is smaller than a diameter at the side of the electrode pad 121. The filled resin layer 124 may be formed by using the same reinforcing member and the same insulating resin as the reinforcing insulating layer 123.

The electronic component 130 is, for example, an electronic component, such as a capacitor, and has a function to reduce noise that occurs from the semiconductor element that is mounted on the upper surface 110a of the first wiring structure 110. The electronic component 130 is embedded in the reinforcing insulating layer 123. Specifically, the filling resin 135 is filled around the electronic component 130, so that the electronic component 130 is embedded in the second wiring structure 120. A reinforcing member other than glass fiber, such as carbon fiber, may be used as a reinforcing member for the reinforcing insulating layer 123.

In this manner, in one embodiment, the electronic component 130 is embedded in the second wiring structure 120, so that the semiconductor element that is mounted on the upper surface 110a of the first wiring structure 110 and the electronic component 130 are connected to each other via only the wiring of the first wiring board 100 that is a relay board. Specifically, the semiconductor element and the electronic component 130 are connected to each other via the electrode pad 111, the wiring layer 116, and the via 117 of the first wiring board 100, the wiring layer 125, the via 126, the wiring 127, and the via 128. With this configuration, as compared to a structure in which a semiconductor element and an electronic component that is mounted on a main board are connected to each other via wiring of the relay board and wiring of the main board, it is possible to reduce a length of the wiring between the semiconductor element and the electronic component 130, so that it is possible to reduce inductance of the wiring. As a result, it is possible to effectively reduce, in the electronic component 130, noise from the semiconductor element, so that is possible to prevent spread of noise from the semiconductor element.

Furthermore, in one embodiment, the electronic component 130 is embedded in the second wiring structure 120 that includes a reinforcing member. Therefore, it is possible to increase resistance against stress that is applied to the electronic component 130, so that it is possible to reduce the possibility of damage of the electronic component 130.

Moreover, in one embodiment, the thickness of the second wiring structure 120 is larger than that of the first wiring structure 110. Therefore, it is possible to reduce restriction on a component size of the electronic component 130 that is embedded in the second wiring structure 120.

Furthermore, in one embodiment, the first wiring structure 110 is formed on the glass support 300 such that the upper surface 110a serving as a mounting surface of the semiconductor element is oriented toward the glass support 300. Therefore, the strength the first wiring board 100 increases, and handling easiness of the first wiring board 100 is improved.

Meanwhile, the glass support 300 illustrated in FIG. 2 is separated from the first wiring board 100 after the first wiring board 100 and the second wiring board 200 are bonded together, but a timing of separation of the glass support 300 is not limited to this example. For example, the glass support 300 may be separated at the time the first wiring board 100 is formed on the glass support 300 illustrated in FIG. 2.

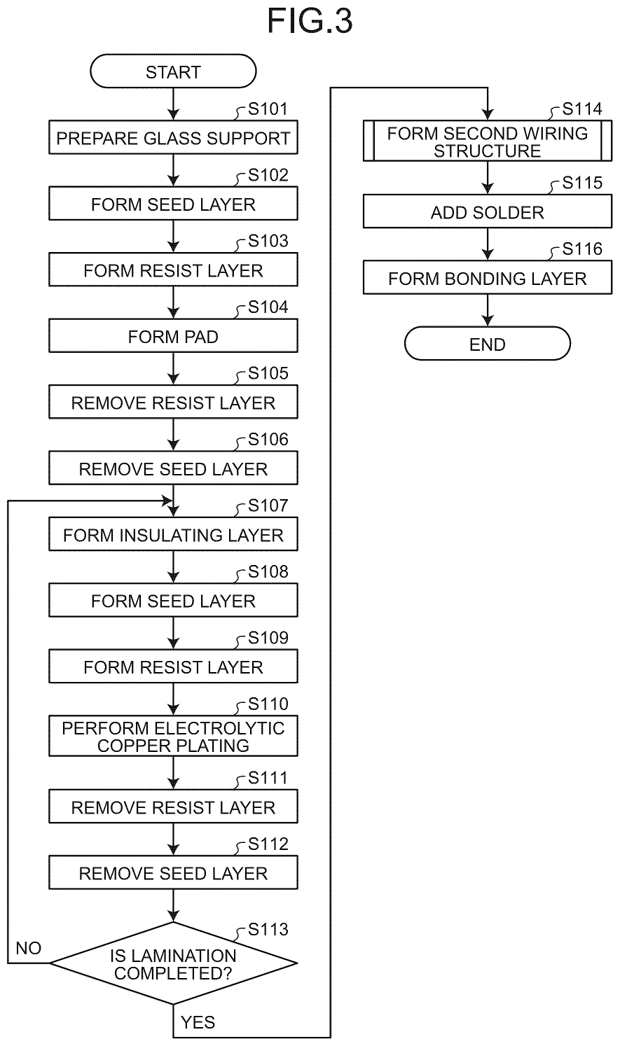

A manufacturing method of manufacturing the first wiring board 100 illustrated in FIG. 2 will be described in detail below with reference to a flowchart illustrated in FIG. 3. FIG. 3 is a flowchart illustrating a method of manufacturing the first wiring board 100 according to one embodiment.

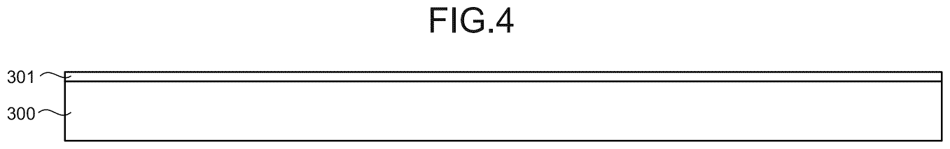

First, the glass support 300 that serves as a support for manufacturing the first wiring board 100 is prepared (Step S101). Specifically, as illustrated in FIG. 4 for example, the release layer 301 is formed on a flat upper surface of the glass support 300. FIG. 4 is a diagram illustrating a specific example of the glass support 300. Meanwhile, it may be possible to use a different support other than the glass support 300, and it may be possible to use metal, silicon, ceramic, or the like as a material of the different support.

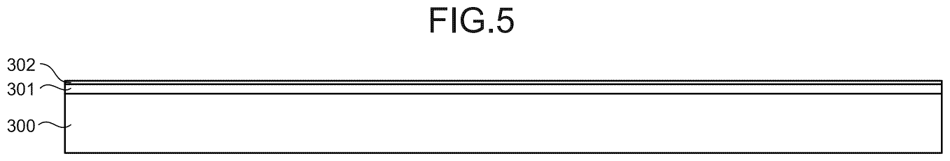

Further, as illustrated in FIG. 5 for example, a seed layer 302 is formed on an upper surface of the release layer 301 of the glass support 300 by, for example, copper sputtering (Step S102). FIG. 5 is a diagram illustrating a specific example of a seed layer formation process.

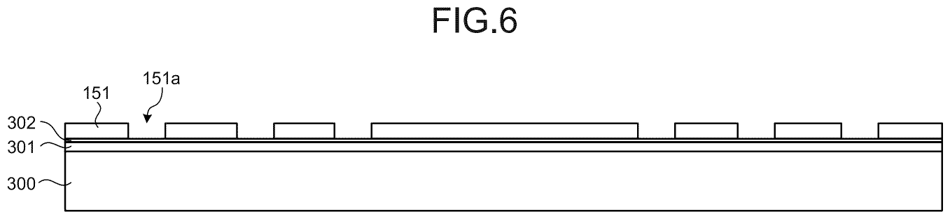

Furthermore, as illustrated in FIG. 6 for example, a resist layer 151 that includes an opening portion 151a is formed on the seed layer 302 (Step S103). The resist layer 151 is formed by using, for example, a dry resist film, and the opening portion 151a may be formed by, for example, photolithography or laser processing. FIG. 6 is a diagram illustrating a specific example of a resist layer formation process.

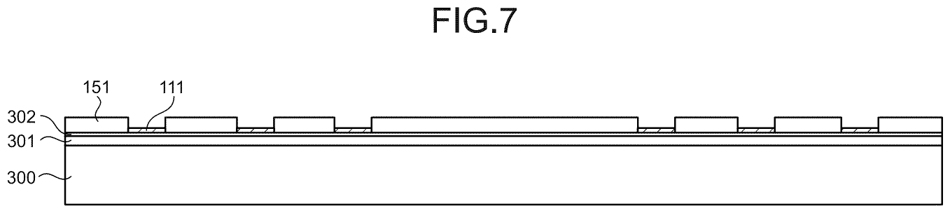

After formation of the resist layer 151, the electrode pad 111 is formed by electrolytic copper plating with power supply from the seed layer 302 (Step S104). Specifically, as illustrated in FIG. 7 for example, the electrode pad 111 is formed on the seed layer 302 that is exposed from the opening portion 151a of the resist layer 151. FIG. 7 is a diagram illustrating a specific example of a resist layer formation process.

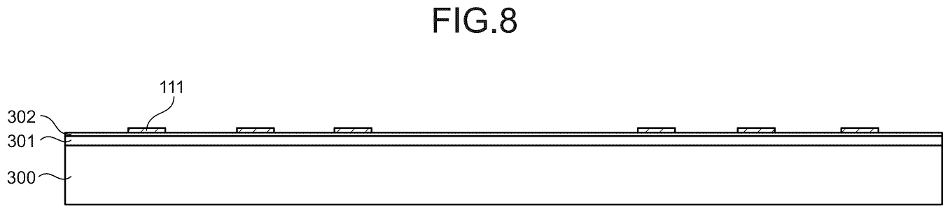

Subsequently, as illustrated in FIG. 8 for example, the resist layer 151 is removed (Step S105). FIG. 8 is a diagram illustrating a specific example of a resist layer removal process. The resist layer 151 is removed by using, for example, caustic soda or amine alkaline remover.

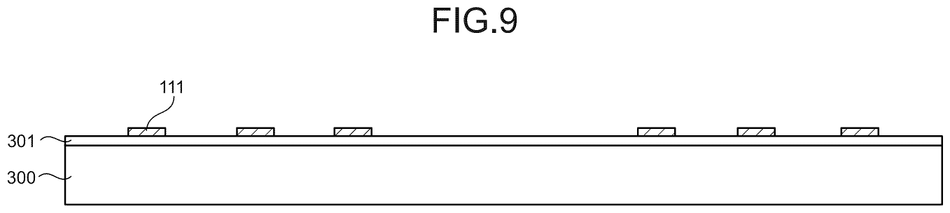

After removal of the resist layer 151, an unneeded portion of the seed layer 302 is removed by flash etching (Step S106). Specifically, the seed layer 302 that is exposed without coming into contact with the electrode pad 111 is dissolved by an etching liquid that dissolves the seed layer 302, and, as illustrated in FIG. 9 for example, the release layer 301 other than a portion that comes into contact with the electrode pad 111 is exposed. FIG. 9 is a diagram illustrating a specific example of a seed layer removal process. Meanwhile, the seed layer 302 that comes into contact with the electrode pad 111 remains after the flash etching, but illustration thereof is omitted in FIG. 9.

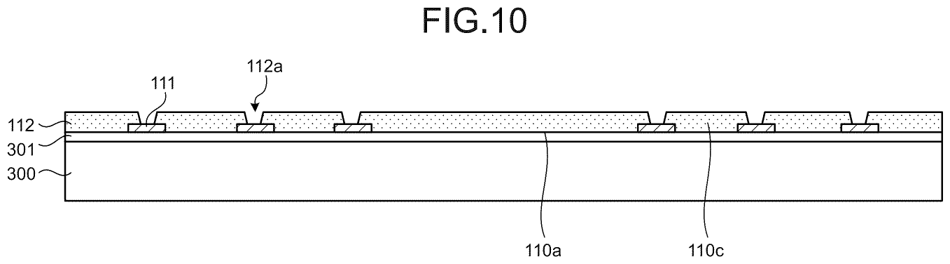

After removal of the seed layer 302, the first wiring structure 110 is formed on the release layer 301. First, the insulating layer 110c of the first thin film layer 112 is formed on the release layer 301 so as to cover the electrode pad 111 (Step S107). The insulating layer 110c is formed by using photosensitive insulating resin, and a via hole is formed by photolithography. Specifically, as illustrated in FIG. 10 for example, a via hole 112a from which an upper surface of the electrode pad 111 is exposed is formed at a position corresponding to the electrode pad 111 on the insulating layer 110c of the first thin film layer 112. FIG. 10 is a diagram illustrating a specific example of an insulating layer formation process. The surface (lower surface) of the first thin film layer 112 at the side of the upper surface of the glass support 300 forms the upper surface 110a of the first wiring structure 110 that serves as a mounting surface of the semiconductor element, and the electrode pad 111 is exposed from the first thin film layer 112 on the upper surface 110a of the first wiring structure 110.

Further, a seed layer is formed on the surface of the insulating layer 110c of the first thin film layer 112 by, for example, copper sputtering (Step S108).

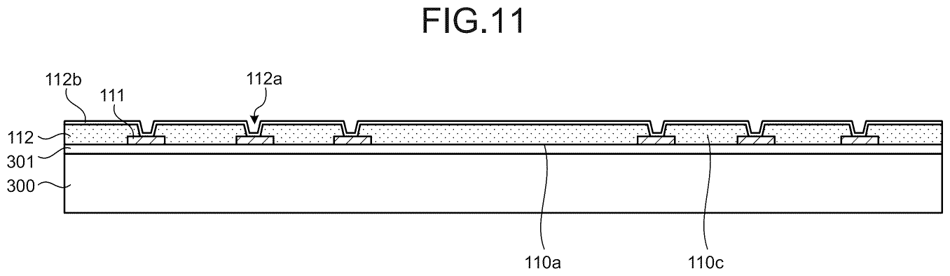

Specifically, as illustrated in FIG. 11 for example, a seed layer 112b that covers the surface of the electrode pad 111 exposed from the via hole 112a and the surface of the insulating layer 110c of the first thin film layer 112 including an inner wall of the via hole 112a is formed. FIG. 11 is a diagram illustrating a specific example of a seed layer formation process.

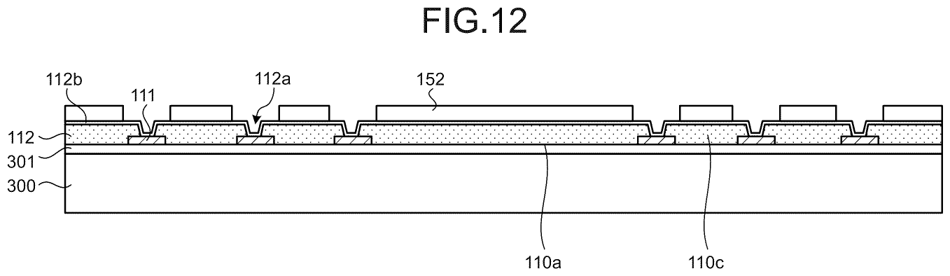

After formation of the seed layer 112b, a resist layer for forming the wiring layer 116 of the first thin film layer 112 is formed on the seed layer 112b (Step S109). Specifically, as illustrated in FIG. 12 for example, a resist layer 152, in which an opening is arranged in a wiring pattern formation portion for fine wiring, is formed on the seed layer 112b by patterning using exposure and development. FIG. 12 is a diagram illustrating a specific example of a resist layer formation process.

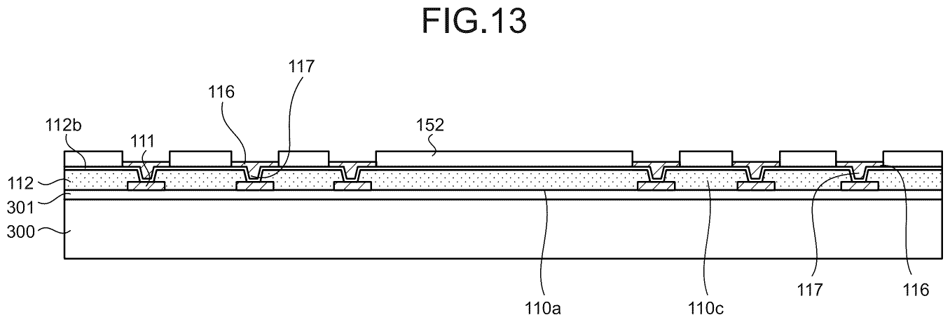

After formation of the resist layer 152, the wiring layer 116 and the via 117 of the first thin film layer 112 are formed on the seed layer 112b that is exposed from the opening of the resist layer 152 by, for example, electrolytic copper plating with power supply from the seed layer 112b (Step S110). Specifically, as illustrated in FIG. 13 for example, electrolytic copper is filled in the via hole 112a to form the via 117, and the wiring layer 116 that includes fine wiring is formed. FIG. 13 is a diagram illustrating a specific example of an electrolytic copper plating process.

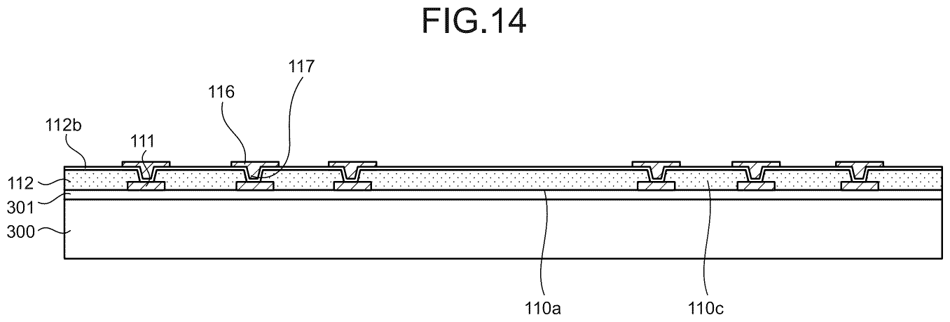

After formation of the wiring layer 116 and the via 117 of the first thin film layer 112 by electrolytic copper plating, the resist layer 152 is removed as illustrated in FIG. 14 for example (Step S111). FIG. 14 is a diagram illustrating a specific example of a resist layer removal process. The resist layer 152 is removed by using, for example, caustic soda or amine alkaline remover.

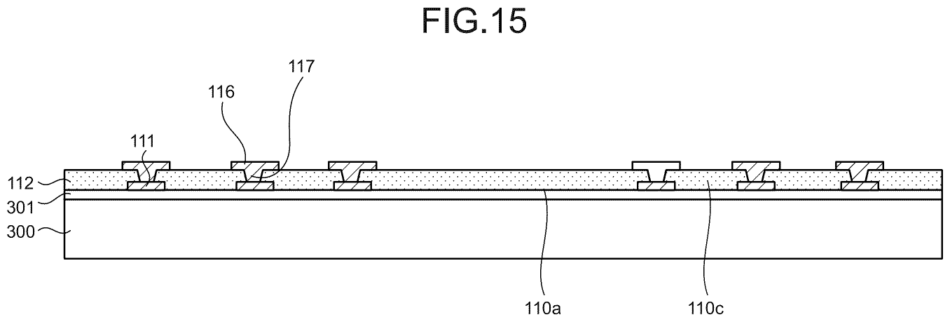

After removal of the resist layer 152, an unneeded portion of the seed layer 112b is removed by flash etching (Step S112), so that the first thin film layer 112 of the first wiring structure 110 is completed. Specifically, as illustrated in FIG. 15 for example, the seed layer 112b other than a portion that comes into contact with the wiring layer 116 and the via 117 is removed, and the insulating layer 110c and the first thin film layer 112 that includes the wiring layer 116 and the via 117 are laminated on the release layer 301. FIG. 15 is a diagram illustrating a specific example of a seed layer removal process. Meanwhile, the seed layer 112b that comes into contact with the wiring layer 116 and the via 117 remains after the flash etching, but illustration thereof is omitted in FIG. 15.

It may be possible to laminate a plurality of thin film layers that form the first wiring structure 110, and therefore, whether or not to terminate the process is determined based on whether or not lamination of thin film layers is completed (Step S113). If lamination of thin film layers is not completed (No at Step S113), the same process as the formation of the first thin film layer 112 as described above is repeated, and the second thin film layer 113 and subsequent layers are formed.

In contrast, if lamination of thin film layers is completed (Yes at Step S113), the first wiring structure 110 is completed, so that the second wiring structure 120 is formed on the lower surface 110b of the first wiring structure 110 (Step S114). Specifically, the reinforcing insulating layer 123 and the filled resin layer 124 are laminated in sequence on the lower surface 110b of the first wiring structure 110, and the second wiring structure 120 which includes the wiring layer 125, the electrode pad 121, and the wiring 127 and in which the electronic component 130 is embedded is formed. A process of forming the second wiring structure 120 will be described in detail later.

After formation of the second wiring structure 120, the intermediate structure as illustrated in FIG. 2 is formed. Specifically, the intermediate structure in which the first wiring structure 110 and the second wiring structure 120 are formed on the glass support 300 is formed. The first wiring structure 110 and the second wiring structure 120 constitute the first wiring board 100.

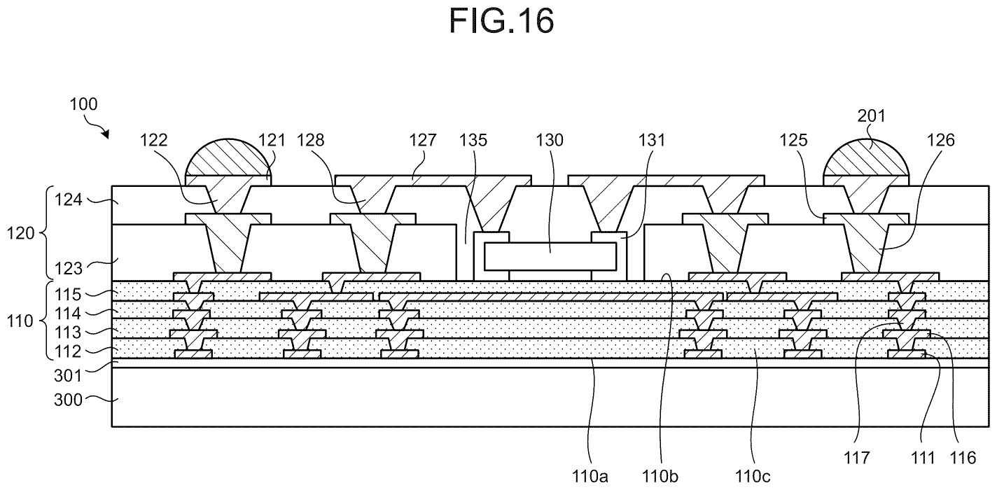

Subsequently, to bond the first wiring board 100 to the second wiring board 200, as illustrated in FIG. 16 for example, the solder 201 is added to the electrode pad 121 of the first wiring board 100 (Step S115). FIG. 16 is a diagram illustrating a specific example of a solder adding process.

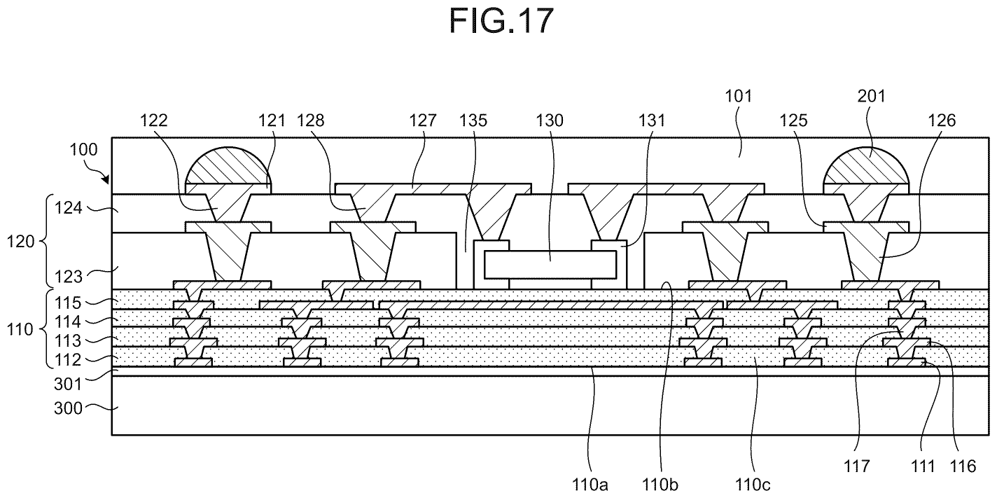

After addition of the solder 201 to the electrode pad 121 of the first wiring board 100, as illustrated in FIG. 16 for example, the bonding layer 101 that covers the electrode pad 121 and the solder 201 is formed at the position of the electrode pad 121 on the lower surface of the second wiring structure 120 (Step S116). FIG. 17 is a diagram illustrating a specific example of a bonding layer formation process.

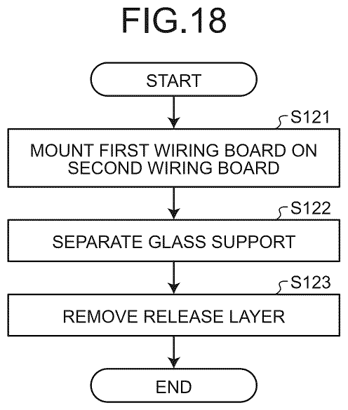

A manufacturing method of manufacturing the board illustrated in FIG. 1 will be described in detail below with reference to a flowchart illustrated in FIG. 18. FIG. 18 is a flowchart illustrating a method of manufacturing the board according to one embodiment.

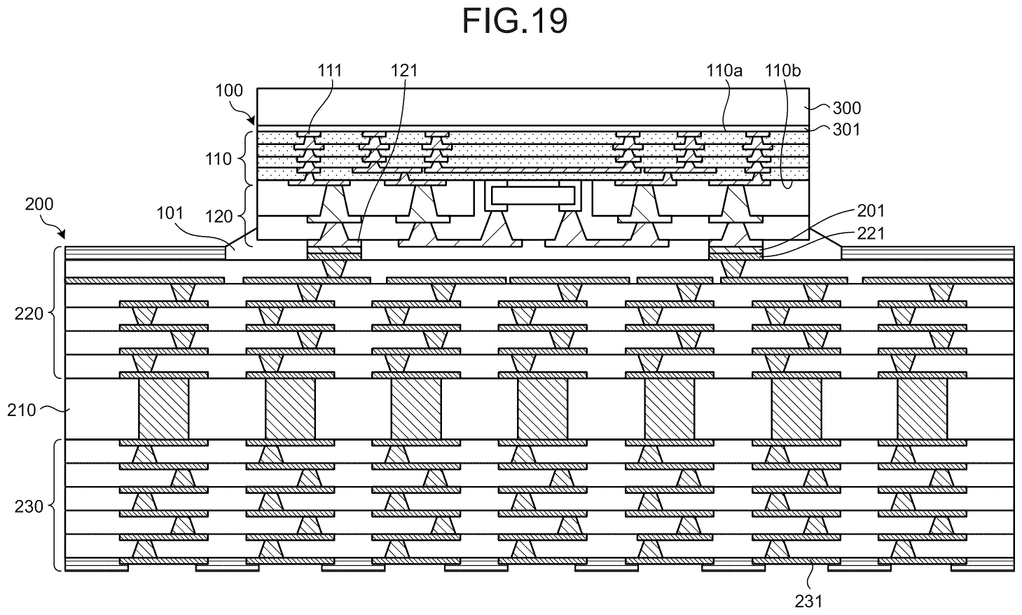

First, the first wiring board 100 that is manufactured on the glass support 300 is mounted on the second wiring board 200 via the bonding layer 101 (Step S121). Specifically, as illustrated in FIG. 19 for example, the first wiring board 100 and the second wiring board 200 are bonded together by the bonding layer 101 such that the electrode pad 121 of the first wiring board 100 and the electrode pad 221 of the second wiring board 200 are connected to each other via the solder 201. FIG. 19 is a diagram illustrating a specific example of the first wiring board mounting process.

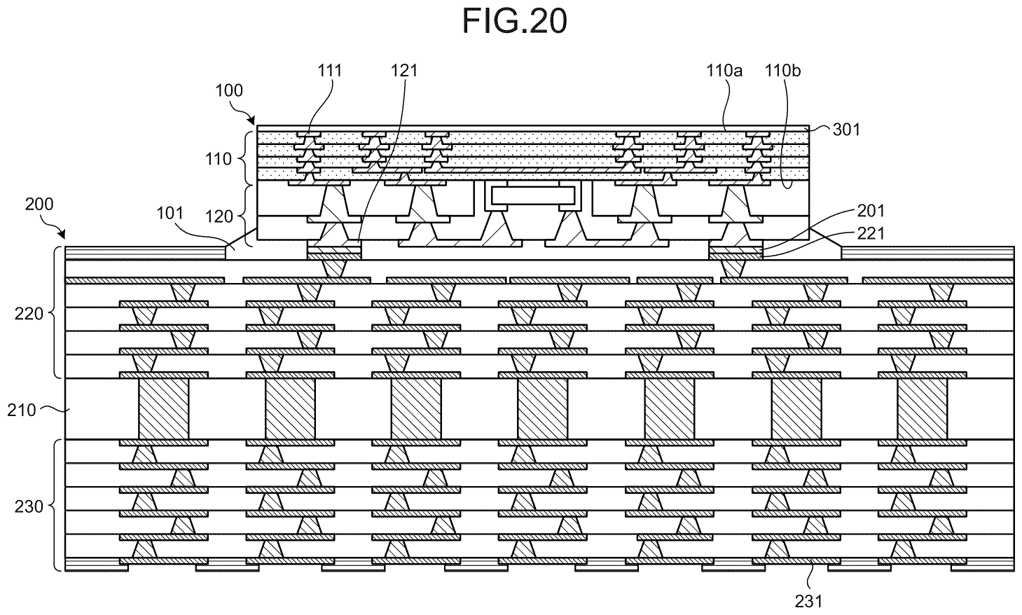

After the first wiring board 100 and the second wiring board 200 are bonded together by the bonding layer 101 and the solder 201, as illustrated in FIG. 20 for example, the glass support 300 is separated from the release layer 301 of the first wiring board 100 (Step S122). FIG. 20 is a diagram illustrating a specific example of a glass support release process.

Further, the release layer 301 is removed (Step S123), so that the laminated wiring board in which the first wiring board 100 and the second wiring board 200 are laminated as illustrated in FIG. 1 is completed.

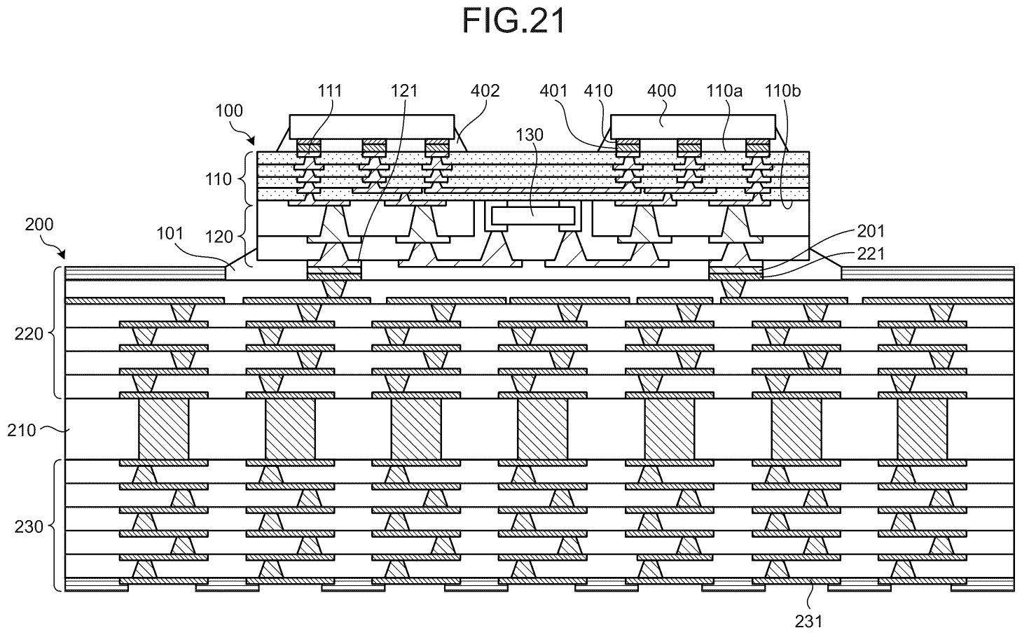

The laminated wiring board illustrated in FIG. 1 may be used for, for example, a semiconductor device on which a semiconductor element, such as a semiconductor chip, is mounted. Specifically, as illustrated in FIG. 21 for example, a semiconductor chip 400 is mounted on the upper surface 110a of the first wiring board 100. FIG. 21 is a diagram illustrating a configuration example of a semiconductor device. An electrode 410 of the semiconductor chip 400 and the electrode pad 111 of the first wiring board 100 are bonded together by a solder 401. Further, a bonded portion of the electrode 410 and the electrode pad 111 is sealed with underfill resin 402. Accordingly, a semiconductor device in which the semiconductor chip 400 is mounted on the first wiring board 100 that is the relay board via the underfill resin 402.

In the semiconductor device as described above, the electronic component 130 is embedded in the second wiring structure 120. Therefore, the semiconductor chip 400 that is mounted on the upper surface 110a of the first wiring structure 110 and the electronic component 130 are connected to each other only via the wiring of the first wiring board 100 that is the relay board. Specifically, the semiconductor chip 400 and the electronic component 130 are connected to each other via the electrode pad 111 of the first wiring board 100, the wiring layer 116, the via 117, the wiring layer 125, the via 126, the wiring 127, and the via 128. Accordingly, as compared to a structure in which the semiconductor chip 400 and the electronic component that is mounted on the main board are connected to each other via the wiring of the relay board and the wiring of the main board, it is possible to reduce the length of the wiring between the semiconductor chip 400 and the electronic component 130, so that it is possible to reduce inductance of the wiring. As a result, it is possible to effectively reduce, in the electronic component 130, noise from the semiconductor chip 400, so that is possible to prevent spread of noise from the semiconductor chip 400.

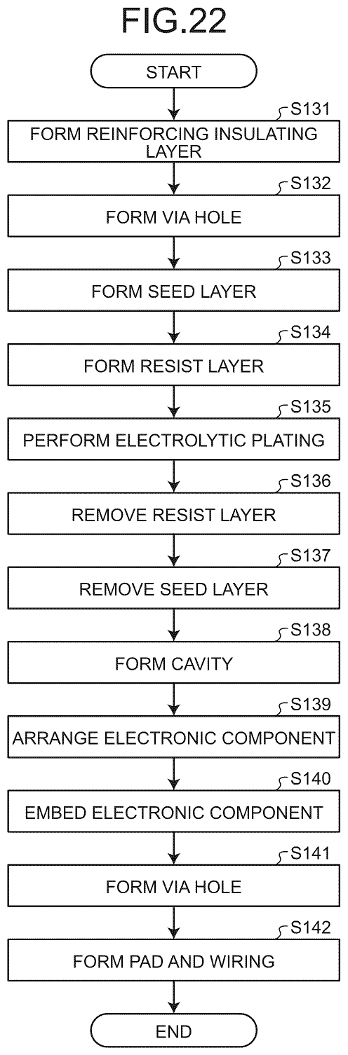

A process of forming the second wiring structure 120 of the first wiring board 100 will be described in detail below with reference to a flowchart illustrated in FIG. 22. FIG. 22 is a flowchart illustrating a method of forming the second wiring structure 120 according to one embodiment. A process of forming the second wiring structure 120 illustrated in FIG. 22 corresponds to Step S114 in FIG. 3.

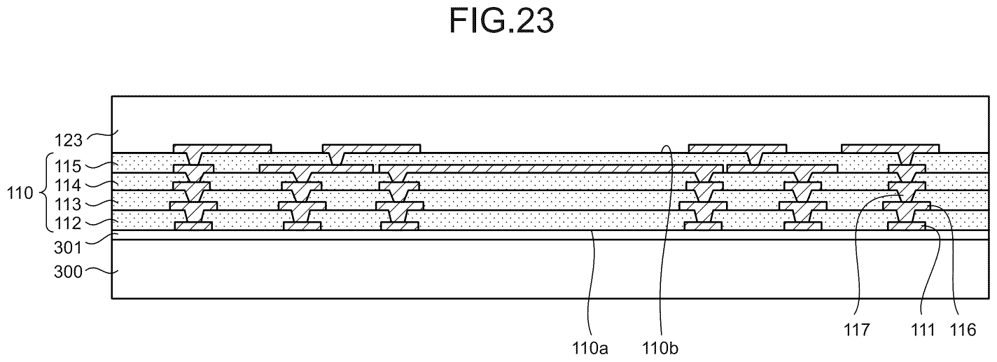

First, the reinforcing insulating layer 123 that covers the wiring layer 116 serving as the uppermost layer of the first wiring structure 110 is formed on the lower surface 110b of the first wiring structure 110 (Step S131). Specifically, as illustrated in FIG. 23 for example, the reinforcing insulating layer 123 that is not cured is laminated on the lower surface 110b of the first wiring structure 110, and the wiring layer 116 is covered by the reinforcing insulating layer 123. The reinforcing insulating layer 123 that is formed on the lower surface 110b of the first wiring structure 110 is thermally cured. FIG. 23 is a diagram illustrating a specific example of a reinforcing insulating layer formation process.

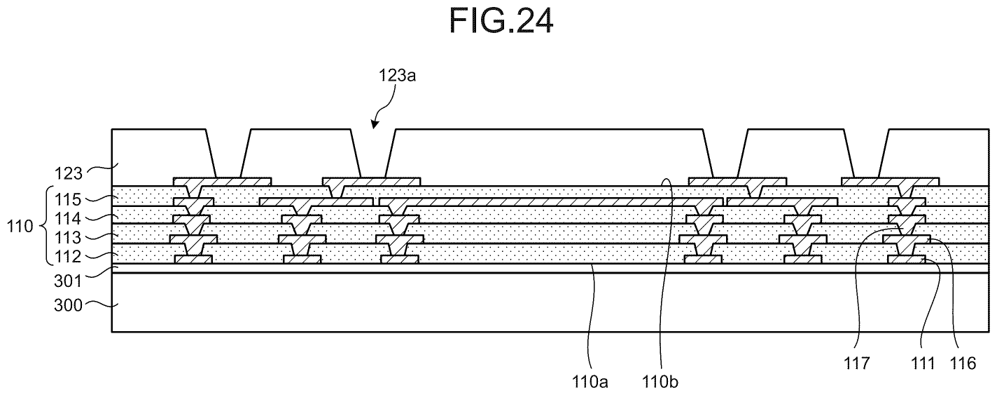

Further, a via hole is formed on the reinforcing insulating layer 123 (Step S132). Specifically, as illustrated in FIG. 24 for example, a via hole 123a that penetrates through the reinforcing insulating layer 123 and that exposes a surface of the wiring layer 116 serving as the uppermost layer of the first wiring structure 110 is formed. FIG. 24 is a diagram illustrating a specific example of a via hole formation process. The via hole 123a may be formed by, for example, laser processing. A residue (smear) of the insulating resin that occurs by the laser processing is removed by a desmear process.

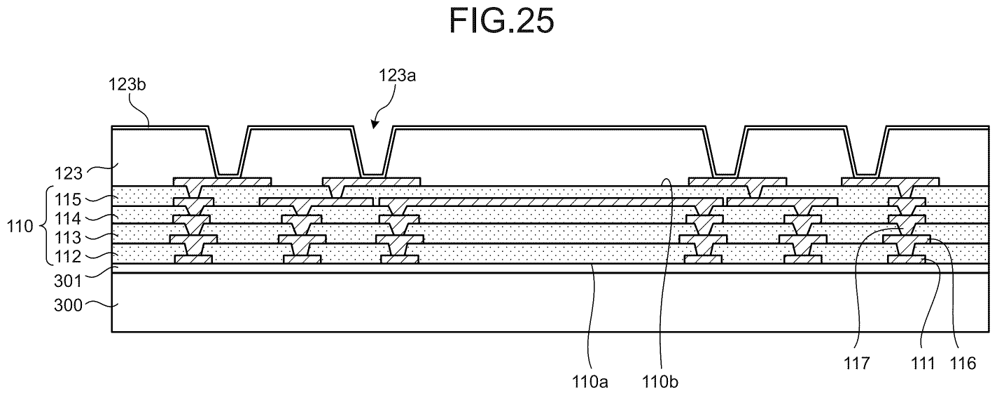

After formation of the via hole 123a, a seed layer is formed on the surface of the reinforcing insulating layer 123 by, for example, copper sputtering (Step S133). Specifically, as illustrated in FIG. 25 for example, a seed layer 123b that covers the surface of the wiring layer 116 exposed from the via hole 123a and the surface of the reinforcing insulating layer 123 including an inner wall of the via hole 123a is formed. FIG. 25 is a diagram illustrating a specific example of a seed layer formation process.

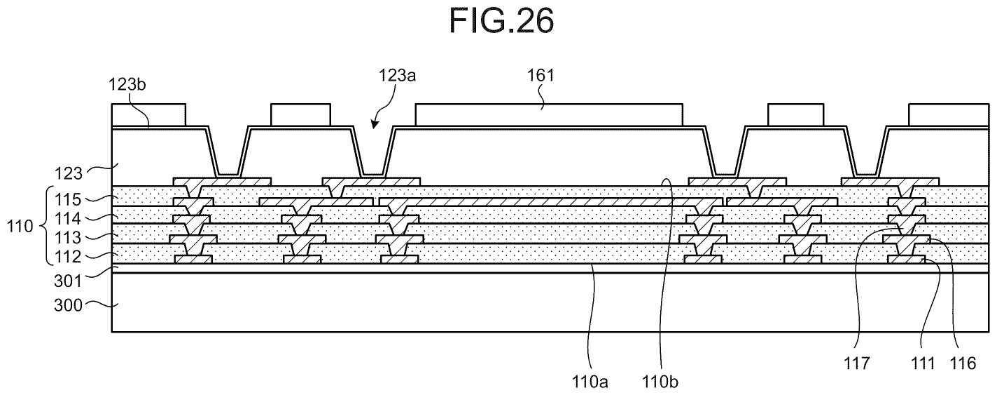

After formation of the seed layer 123b, a resist layer for forming the wiring layer 125 is formed on the seed layer 123b (Step S134). Specifically, as illustrated in FIG. 26 for example, a resist layer 161, in which an opening is arranged in a wiring pattern formation portion, is formed on the seed layer 123b by patterning using exposure and development. FIG. 26 is a diagram illustrating a specific example of a resist layer formation process.

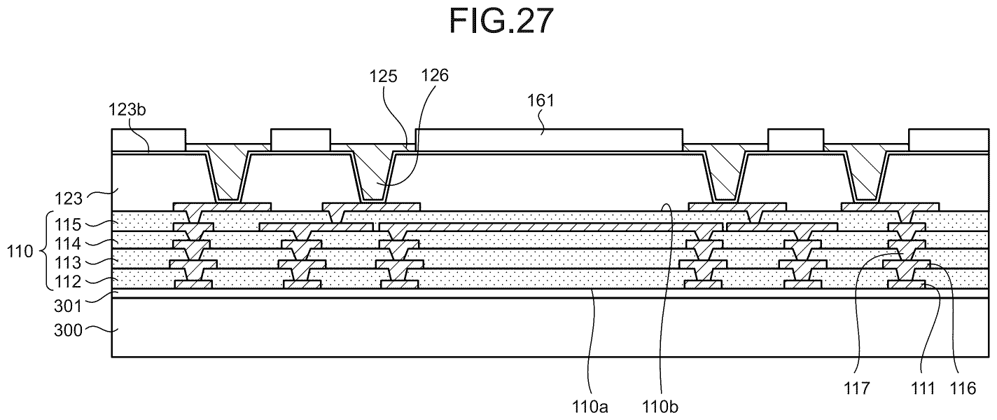

After formation of the resist layer 161, the wiring layer 125 and the via 126 are formed on the seed layer 123b that is exposed from the opening of the resist layer 161 by, for example, electrolytic copper plating with power supply from the seed layer 123b (Step S135). Specifically, as illustrated in FIG. 27 for example, electrolytic copper plating is filled in the via hole 123a to form the via 126, and the wiring layer 125 that has a predetermined wiring pattern is formed. FIG. 27 is a diagram illustrating a specific example of an electrolytic copper plating process. The wiring layer 125 and the via 126 are not arranged in an area in which the electronic component 130 is to be housed in the reinforcing insulating layer 123. In the example illustrated in FIG. 27, the electronic component 130 it to be housed in an area around the center of the reinforcing insulating layer 123, and therefore, the wiring layer 125 and the via 126 are not arranged in this area.

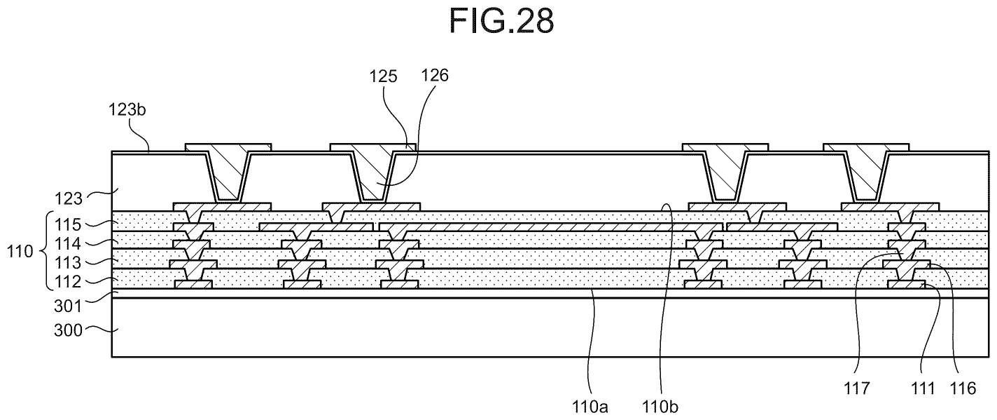

After formation of the wiring layer 125 and the via 126 by electrolytic copper plating, as illustrated in FIG. 28 for example, the resist layer 161 is removed (Step S136). FIG. 28 is a diagram illustrating a specific example of a resist layer removal process. The resist layer 161 is removed by using, for example, caustic soda or amine alkaline remover.

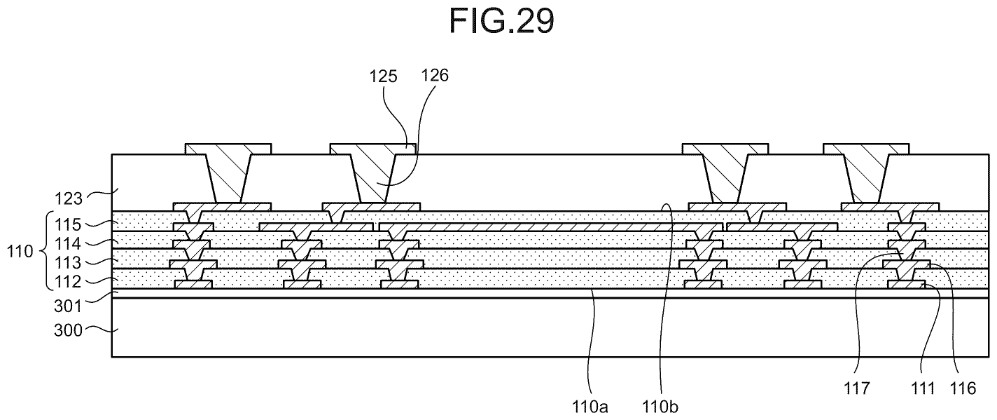

After removal of the resist layer 161, an unneeded portion of the seed layer 123b is removed by flash etching (Step S137). Specifically, the seed layer 123b that is exposed without coming into contact with the wiring layer 125 and the via 126 is removed, and, as illustrated in FIG. 29 for example the reinforcing insulating layer 123 is exposed from the wiring layer 125 and the via 126. FIG. 29 is a diagram illustrating a specific example of a seed layer removal process. Meanwhile, the seed layer 123b that comes into contact with the wiring layer 125 and the via 126 remains after the flash etching, but illustration thereof is omitted in FIG. 29.

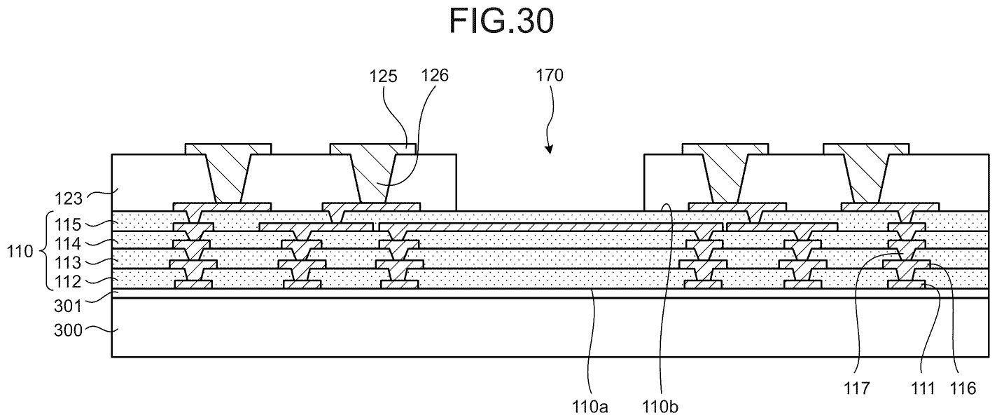

After removal of the seed layer 123b, a cavity is formed in the area in which the electronic component 130 is to be housed in the reinforcing insulating layer 123 (Step S138). Specifically, as illustrated in FIG. 30 for example, the reinforcing insulating layer 123 is noticed in a direction toward the lower surface 110b of the first wiring structure 110, so that a cavity 170 is formed. FIG. 30 is a diagram illustrating a specific example of a cavity formation process. The cavity formation process can be implemented by, for example, performing laser processing using CO₂ laser. The reinforcing insulating layer 123 is cut off up to the lower surface 110b of the first wiring structure 110, so that the lower surface 110b of the first wiring structure 110 is exposed at a bottom surface of the cavity 170.

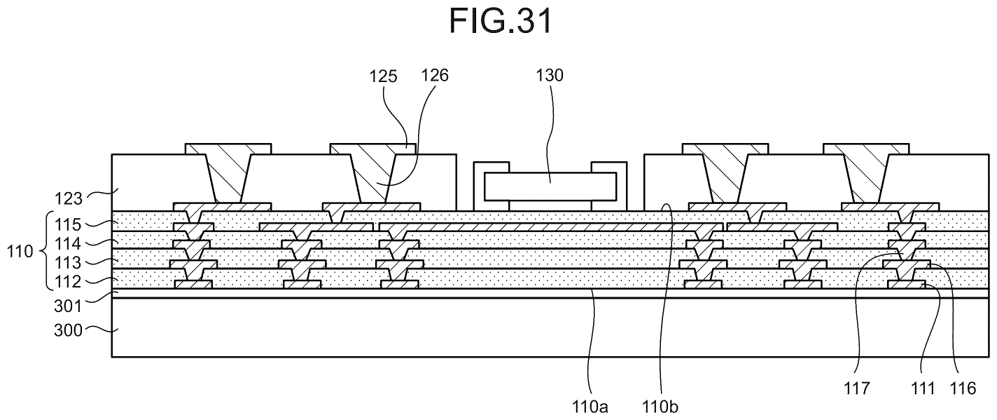

Further, the electronic component 130 is arranged inside the cavity 170 (Step S139). Specifically, as illustrated in FIG. 31 for example, the electronic component 130 is temporarily bonded onto the lower surface 110b of the first wiring structure 110 in the cavity 170 by an adhesive in a semi-cured state (not illustrated). FIG. 31 is a diagram illustrating a specific example of an electronic component arrangement process. For example, an adhesive agent comprised of insulating resin, such as epoxy resin and polyimide resin, may be used as an adhesive agent for temporarily bonding the electronic component 130.

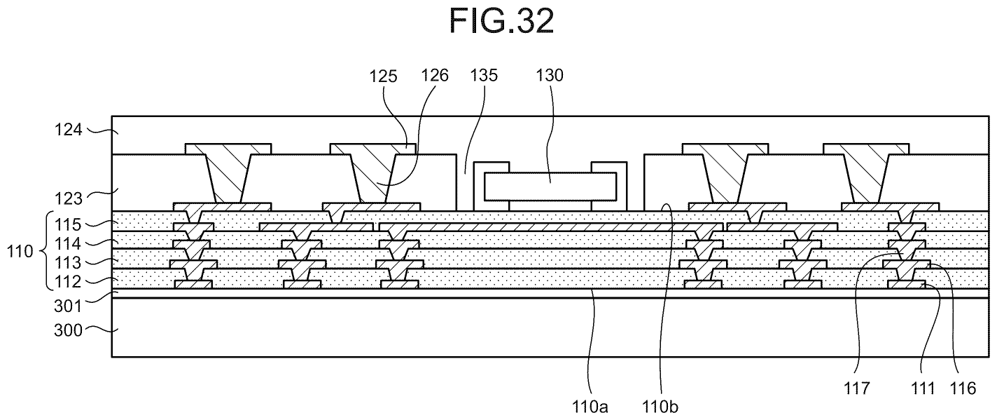

After arrangement of the electronic component 130 in the cavity 170, the filling resin 135 is filled in the cavity 170, so that the electronic component 130 is embedded (Step S140). Specifically, as illustrated in FIG. 32 for example, the filling resin 135 is filled in the cavity 170 and the filled resin layer 124 that extends upward of the electronic component 130 is formed. Accordingly, the electronic component 130 is embedded in the reinforcing insulating layer 123. FIG. 32 is a diagram illustrating a specific example of an electronic component embedding process. After the filling resin 135 is filled in the cavity 170 and the filled resin layer 124 is formed, the resin is thermally cured. At the same time, the adhesive agent by which the electronic component 130 is temporarily bonded is thermally cured, so that the electronic component 130 is fixed to the lower surface 110b of the first wiring structure 110 in the cavity 170. By fixation of the electronic component 130 onto the lower surface 110b of the first wiring structure 110, heat that is generated from the electronic component 130 is conducted to the wiring layer 116 of the first wiring structure 110 and effectively dissipated to the outside of the first wiring structure 110.

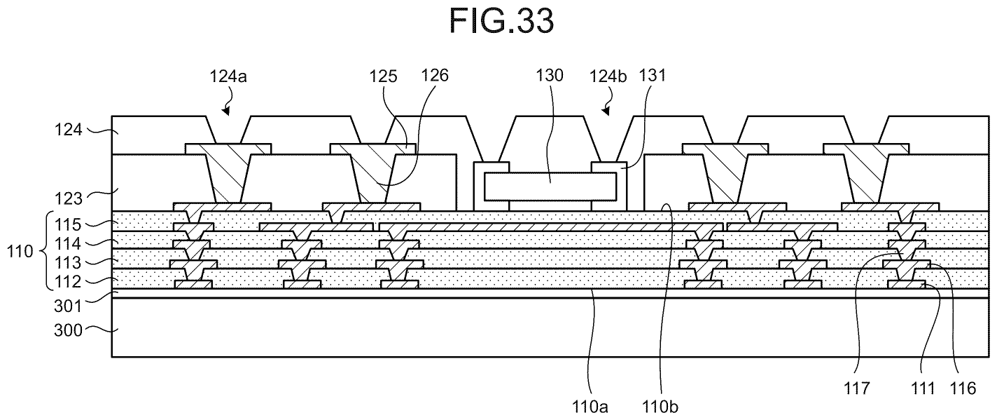

Further, a via hole is formed in the filled resin layer 124 (Step S141). Specifically, as illustrated in FIG. 33 for example, a via hole 124a that penetrates through the filled resin layer 124 and that exposes the wiring layer 125 on the surface of the reinforcing insulating layer 123 and a via hole 124b that penetrates through the filled resin layer 124 and that exposes the electrode 131 of the electronic component 130 are formed. FIG. 33 is a diagram illustrating a specific example of a via hole formation process. The via holes 124a and 124b may be formed by, for example, laser processing.

At positions at which the via holes 124a and 124b are formed, the electrode pad 121 and the wiring 127 on the surface of the filled resin layer 124 are formed (Step S142). The electrode pad 121 and the wiring 127 are formed by, for example, a Semi Additive Process (SAP). The vias 122 and 128 are formed together with the electrode pad 121 and the wiring 127, and one of the electrode pad 121 and the wiring 127 on the surface of the filled resin layer 124 is connected to one of the wiring layer 125 on the surface of the reinforcing insulating layer 123 and the electrode 131 of the electronic component 130. Accordingly, the second wiring structure 120 with the embedded electronic component 130 is completed.

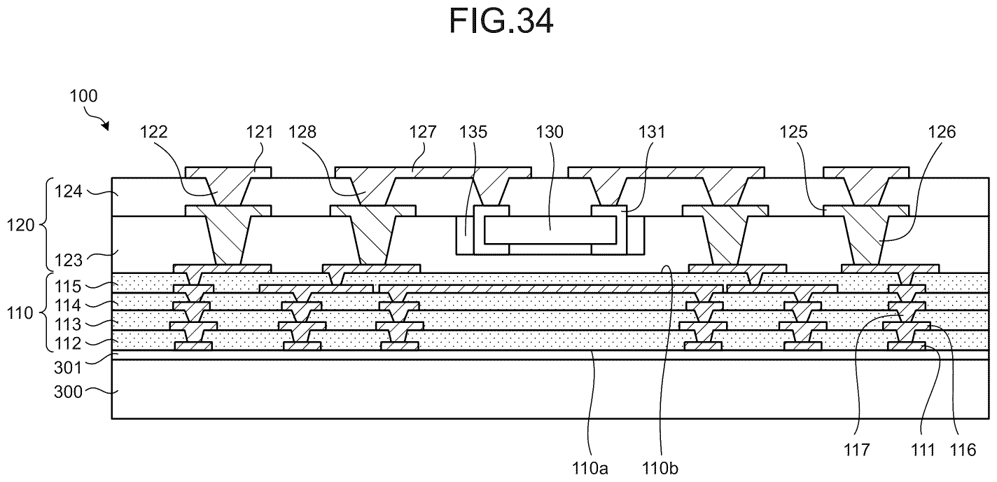

Various modifications of one embodiment will be described below with reference to FIG. 34 to FIG. 43. Meanwhile, in each of the modifications described below, the same components as those of one embodiment are denoted by the same reference symbols, and repeated explanation may be omitted.

FIG. 34 is a diagram illustrating a configuration of the first wiring board 100 according to a first modification of one embodiment. In the first wiring board 100 according to the first modification, the way of fixation of the electronic component 130 that is embedded in the reinforcing insulating layer 123 is different from the embodiment as described above.

Specifically, in the first modification, the cavity of the reinforcing insulating layer 123 does not penetrate until the lower surface 110b of the first wiring structure 110, and the bottom surface of the cavity is formed by the reinforcing insulating layer 123. Further, the electronic component 130 is fixed onto the reinforcing insulating layer 123 that forms the bottom surface of the cavity.

In the first modification, the electronic component 130 is fixed onto the reinforcing insulating layer 123 that forms the bottom surface of the cavity, so that it is possible to arrange the reinforcing insulating layer 123 between the electronic component 130 and the lower surface 110b of the first wiring structure 110. Therefore, it is possible to further increase resistance against stress that is applied to the electronic component 130, so that it is possible to reduce the possibility of damage of the electronic component 130.

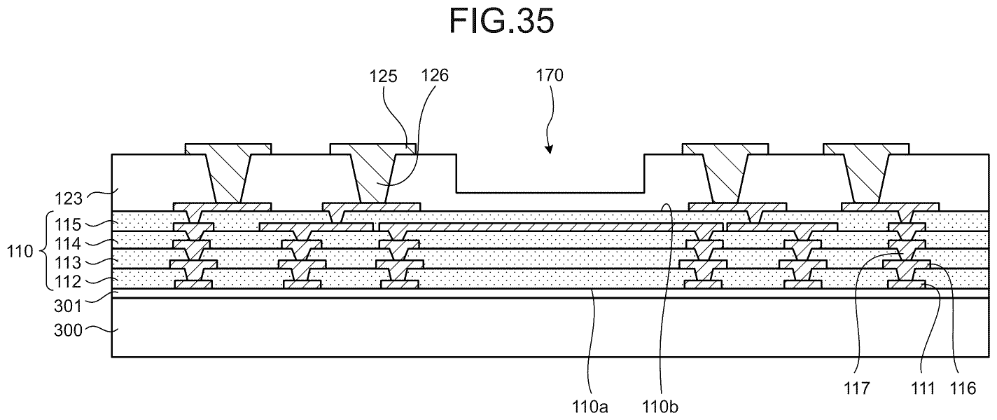

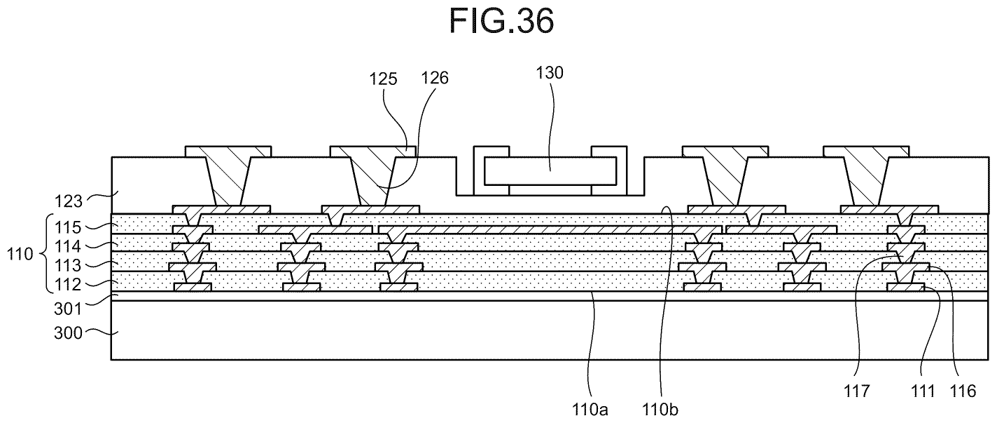

A manufacturing method of manufacturing the first wiring board 100 according to the first modification of one embodiment will be described in detail below with reference to FIG. 35 and FIG. 36. In the manufacturing method of manufacturing the first wiring board 100 according to the first modification, the cavity formation process (Step S138 in FIG. 22) and the electronic component arrangement process (Step S139 in FIG. 22) in the process of forming the second wiring structure 120 are different from those of one embodiment. FIG. 35 is a diagram illustrating a specific example of a cavity formation process. FIG. 36 is a diagram illustrating a specific example of an electronic component arrangement process.

After removal of the seed layer 123b, a cavity is formed in an area in which the electronic component 130 is to be housed in the reinforcing insulating layer 123. Specifically, as illustrated in FIG. 35 for example, the reinforcing insulating layer 123 is cut off up to a certain position that does not reach the lower surface 110b of the first wiring structure 110 and the cavity 170 is formed. The bottom surface of the cavity 170 is formed by the reinforcing insulating layer 123.

Then, the electronic component 130 is arranged inside the cavity 170. Specifically, as illustrated in FIG. 36 for example, the electronic component 130 is temporarily bonded onto the reinforcing insulating layer 123 that is located at the bottom surface of the cavity 170 by an adhesive in a semi-cured state (not illustrated). Then, in the subsequent electronic component embedding process, the filled resin layer 124 is thermally cured and the adhesive agent by which the electronic component 130 is temporarily bonded are thermally cured at the same time, so that the electronic component 130 is fixed onto the reinforcing insulating layer 123 that is located at the bottom surface of the cavity 170. By fixation of the electronic component 130 onto the reinforcing insulating layer 123 that is located on the bottom surface of the cavity 170, the reinforcing insulating layer 123 is arranged between the electronic component 130 and the lower surface 110b of the first wiring structure 110, resistance against stress that is applied to the electronic component 130 is further increased. Thereafter, the processes from Step S140 in FIG. 22 are performed, so that the first wiring board 100 of the first modification is completed.

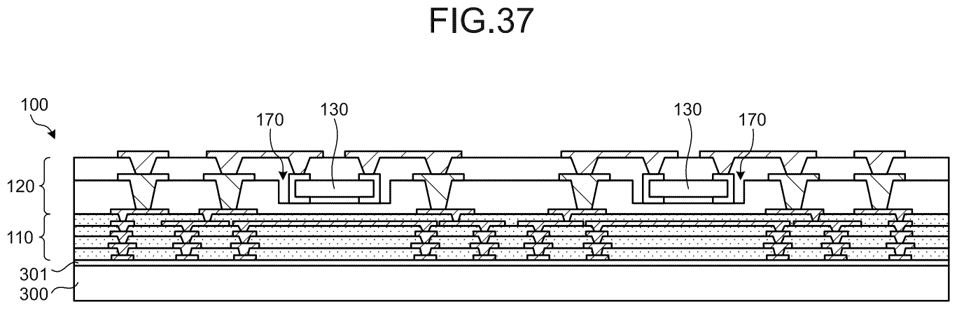

FIG. 37 is a diagram illustrating a configuration of the first wiring board 100 according to a second modification of one embodiment. The first wiring board 100 according to the second modification of one embodiment is different from the first modification as described above in that the plurality of electronic components 130 are embedded in the second wiring structure 120.

Specifically, in the second modification, the plurality of cavities 170 are formed in the reinforcing insulating layer 123 of the second wiring structure 120, and the plurality of electronic components 130 are located in the respective cavities 170. Further, the filled resin layer 124 of the second wiring structure 120 is filled in the plurality of cavities 170 and covers the plurality of electronic components 130. Accordingly, the plurality of electronic components 130 are embedded in the second wiring structure 120.

In this manner, in the second modification, the plurality of electronic components 130 are embedded in the second wiring structure 120, and it is possible to effectively reduce, in the plurality of electronic components 130, noise from the semiconductor element, so that it is possible to further prevent spread of noise from the semiconductor element.

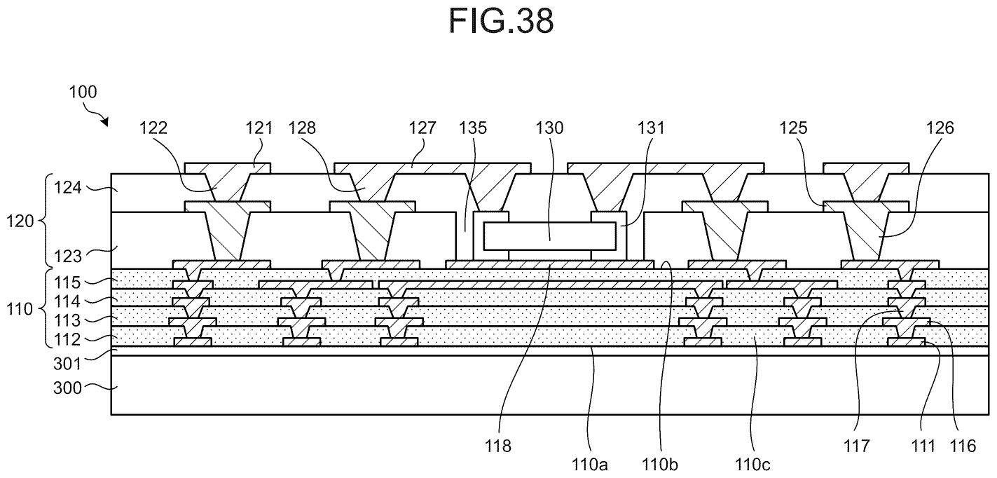

FIG. 38 is a diagram illustrating a configuration of the first wiring board 100 according to a third modification of one embodiment. In the first wiring board 100 according to the third modification, the way of fixation of the electronic component 130 that is embedded in the reinforcing insulating layer 123 is different from the embodiment as described above.

Specifically, in the third modification, a pad 118 is formed on the wiring layer 116 that serves as the uppermost layer of the first wiring structure 110, and the cavity of the reinforcing insulating layer 123 reaches the pad 118. Meanwhile, the pad 118 may be formed by using a resist that has an opening corresponding to a shape of the pad 118, at the time of formation of the wiring layer 116. Further, the electronic component 130 is fixed onto the pad 118 that is exposed from the bottom surface of the cavity of the reinforcing insulating layer 123.

In the third modification, by fixation of the electronic component 130 onto the pad 118 of the wiring layer 116, heat that is generated from the electronic component 130 is conducted to the wiring layer 116 of the first wiring structure 110 and effectively dissipated to the outside of the first wiring structure 110.

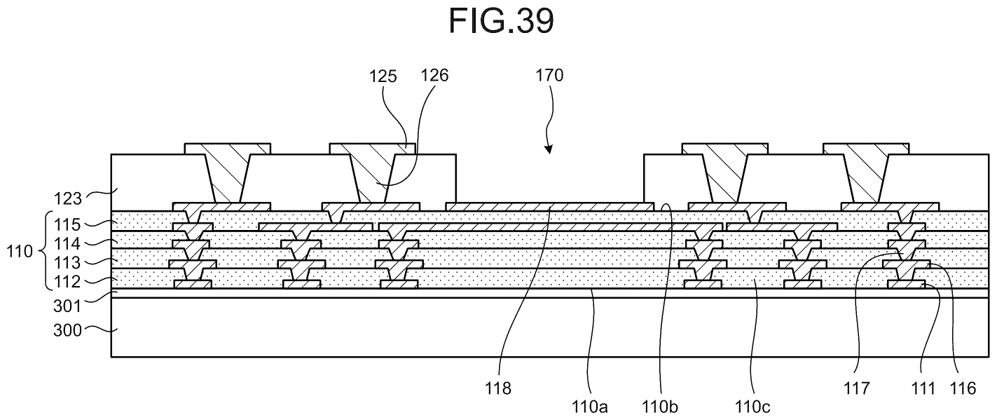

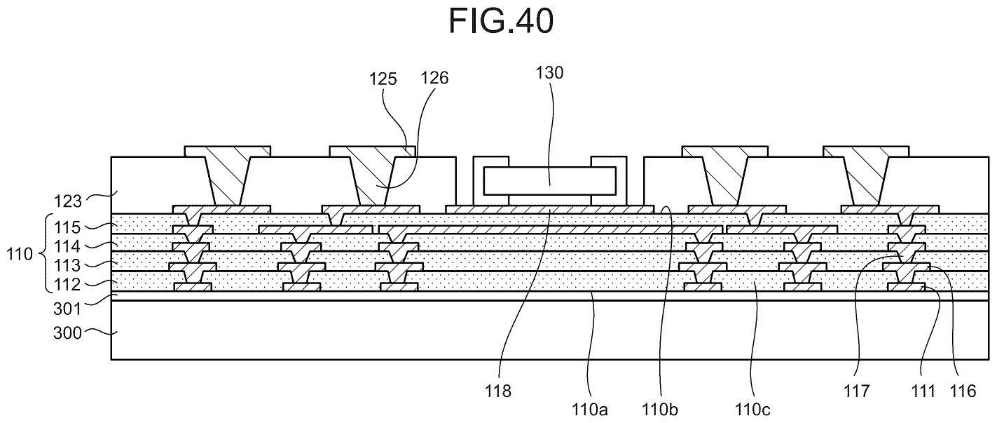

A manufacturing method of manufacturing the first wiring board 100 according to the third modification of one embodiment will be described in detail below with reference to FIG. 39 and FIG. 40. In the manufacturing method of manufacturing the first wiring board 100 according to the third modification, the cavity formation process (Step S138 in FIG. 22) and the electronic component arrangement process (Step S139 in FIG. 22) in the process of forming the second wiring structure 120 are different from those of one embodiment. FIG. 39 is a diagram illustrating a specific example of a cavity formation process. FIG. 40 is a diagram illustrating a specific example of an electronic component arrangement process. Meanwhile, in FIG. 39, it is assumed that the pad 118 is formed on the wiring layer 116 serving as the uppermost layer of the first wiring structure 110 before the cavity formation process is performed.

After removal of the seed layer 123b, a cavity is formed in an area in which the electronic component 130 is to be housed in the reinforcing insulating layer 123. Specifically, as illustrated in FIG. 39 for example, the reinforcing insulating layer 123 is cut off up to the pad 118 and the cavity 170 is formed. The cavity formation process may be implemented by, for example, performing laser processing using CO₂ laser. In the laser processing, the pad 118 functions as a stop layer for laser light, so that the cavity 170 with a flat bottom surface is obtained. The pad 118 is exposed from the bottom surface of the cavity 170. The pad 118 has planar shape (for example, a rectangle) with a larger size than a planar shape of the bottom surface of the cavity 170. Therefore, side surfaces of the pad 118 are located on outer sides of side surfaces of the cavity 170.

Further, the electronic component 130 is arranged inside the cavity 170. Specifically, as illustrated in FIG. 40 for example, the electronic component 130 is temporarily bonded onto the pad 118 that is located on the bottom surface of the cavity 170 by an adhesive in a semi-cured state (not illustrated). Then, in the subsequent electronic component embedding process, the filled resin layer 124 is thermally cured and the adhesive agent by which the electronic component 130 is temporarily bonded are thermally cured at the same time, so that the electronic component 130 is fixed onto the pad 118 that is located on the bottom surface of the cavity 170. By fixation of the electronic component 130 on the pad 118 of the wiring layer 116, heat that is generated from the electronic component 130 is conducted to the wiring layer 116 of the first wiring structure 110 and effectively dissipated to the outside of the first wiring structure 110. Thereafter, the processes from Step S140 in FIG. 22 are performed, so that the first wiring board 100 of the third modification is completed.

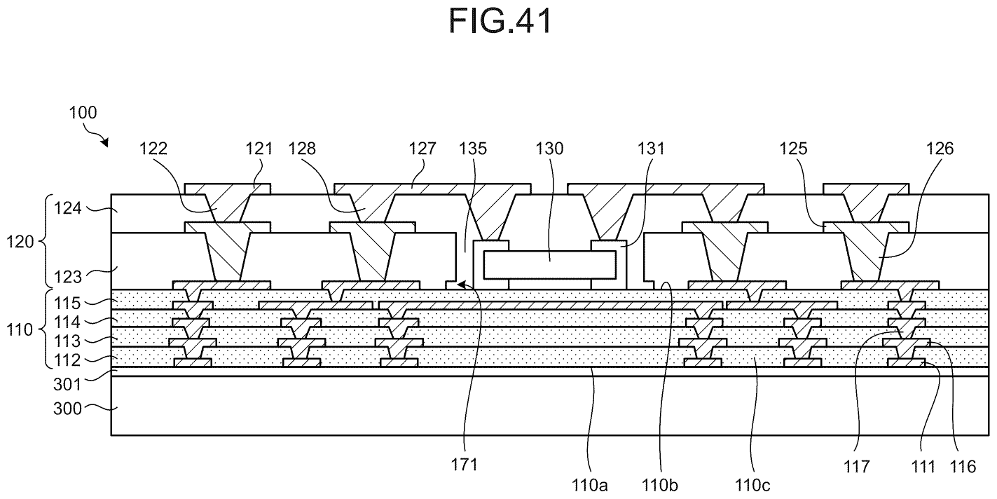

FIG. 41 is a diagram illustrating a configuration of the first wiring board 100 according to the fourth modification of one embodiment. In the first wiring board 100 according to the fourth modification, the structure of the cavity of the reinforcing insulating layer 123 and the structure of the filled resin layer 124 are different from those of the embodiment as described above.

Specifically, in the fourth modification, side surfaces of the cavity of the reinforcing insulating layer 123 include recessed portions 171 at positions adjacent to the bottom surface of the cavity. Then, a part of the filled resin layer 124 is stored in the recessed portions 171 of the cavity.

In the fourth modification, a part of the filled resin layer 124 is stored in the recessed portions of the cavity, so that it is possible to improve adhesiveness of the filled resin layer 124 and the cavities of the reinforcing insulating layer 123 by the anchor effect.

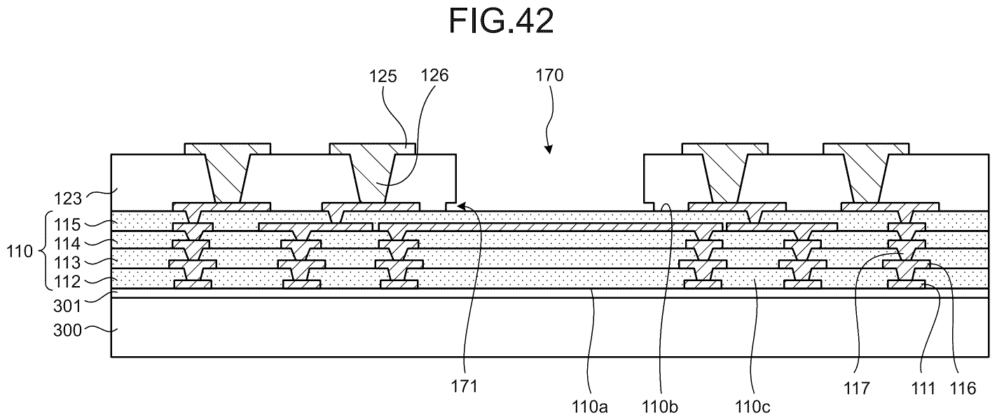

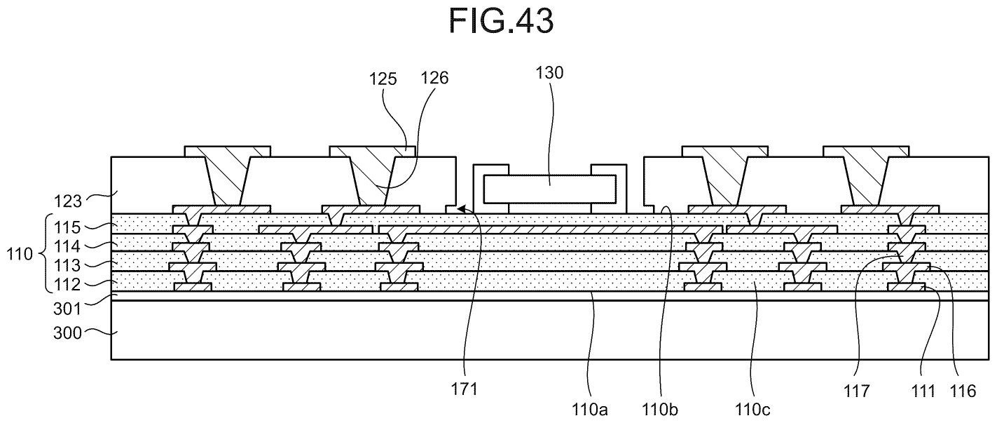

Subsequently, a manufacturing method of manufacturing the first wiring board 100 according to a fourth modification of one embodiment will be described in detail below with reference to FIG. 42 and FIG. 43. The manufacturing method of manufacturing the first wiring board 100 according to the fourth modification is different from the third modification in that a recessed portion formation process is added between the cavity formation process and the electronic component arrangement process. Further, the manufacturing method of manufacturing the first wiring board 100 according to the fourth modification is different from the third modification in that the electronic component arrangement process. FIG. 42 is a diagram illustrating a specific example of the recessed portion formation process. FIG. 43 is a diagram illustrating a specific example of the electronic component arrangement process.

After the cavity 170 that reaches the pad 118 is formed on the reinforcing insulating layer 123 (see FIG. 39), the recessed portions 171 are formed on the side surfaces of the cavity 170. Specifically, the pad 118 is removed by etching and the recessed portions 171 are formed on the side surfaces of the cavity 170 as illustrated in FIG. 42 for example. The lower surface 110b of the first wiring structure 110 is exposed from the bottom surface of the cavity 170.

Further, the electronic component 130 is arranged inside the cavity 170. Specifically, as illustrated in FIG. 43 for example, the electronic component 130 is temporarily bonded onto the lower surface 110b of the first wiring structure 110 in the cavity 170 by an adhesive in a semi-cured state (not illustrated). Furthermore, in the subsequent electronic component embedding process, the filled resin layer 124 is thermally cured and the adhesive agent by which the electronic component 130 is temporarily bonded are thermally cured at the same time, so that the electronic component 130 is fixed onto the lower surface 110b of the first wiring structure 110 inside the cavity 170. Moreover, in the electronic component embedding process, a part of the filled resin layer 124 is stored in the recessed portions 171 of the cavity, so that it is possible to improve adhesiveness of the filled resin layer 124 and the cavity 170 of the reinforcing insulating layer 123 by the anchor effect. Thereafter, the processes from Step S140 in FIG. 22 are performed, so that the first wiring board 100 of the fourth modification is completed.

As described above, a wiring board (as one example, the first wiring board 100) according to one embodiment includes a first wiring structure (as one example, the first wiring structure 110) and a second wiring structure (as one example, the second wiring structure 120). The first wiring structure includes a mounting surface (as one example, the upper surface 110a) for a semiconductor element and a back surface (as one example, the lower surface 110b) on an opposite side of the mounting surface the mounting surface. The second wiring structure is formed on the back surface of the first wiring structure. The second wiring structure includes a reinforcing insulating layer (as one example, the reinforcing insulating layer 123), an electronic component (as one example, the electronic component 130), the filled resin layer (as one example, the filled resin layer 124). The reinforcing insulating layer is formed on the back surface of the first wiring structure. The electronic component is arranged in a cavity (as one example, the cavity 170) that is formed by cutting off the reinforcing insulating layer in a direction toward the back surface of the first wiring structure. The filled resin layer is filled in the cavity and covers the electronic component. With this configuration, it is possible to prevent spread of noise from the semiconductor element.

According to one embodiment of the wiring board disclosed in the present application, it is possible to prevent spread of noise from the semiconductor element.

(Note1) A wiring board manufacturing method comprising:
forming a first wiring structure that includes a mounting surface for a semiconductor element and a back surface on an opposite side of the mounting surface; and
forming a second wiring structure on the back surface of the first wiring structure, wherein
the forming the second wiring structure includes:
   forming a reinforcing insulating layer on the back surface of the first wiring structure;
   forming a cavity by cutting off the reinforcing insulating layer in a direction toward the back surface of the first wiring structure;
   arranging an electronic component in the formed cavity; and
   filling, in the cavity, filling resin that covers the electronic component.

(Note2) The wiring board manufacturing method according to the Note 1, wherein
the forming the first wiring structure includes:
   preparing a support; and
   forming, on the support, the first wiring structure such that the mounting surface comes into contact with the support.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a first wiring structure that includes a mounting surface for a semiconductor element and a back surface on an opposite side of the mounting surface; and
a second wiring structure that is formed on the back surface of the first wiring structure, wherein
the second wiring structure includes
a reinforcing insulating layer that is formed on the back surface of the first wiring structure,
a cavity that is formed by cutting off the reinforcing insulating layer in a direction toward the back surface of the first wiring structure;
an electronic component that is arranged in the cavity; and
a filled resin layer that is filled in the cavity and covers the electronic component.

2. The wiring board according to claim 1, wherein the electronic component is arranged in the cavity that is formed by cutting off the reinforcing insulating layer up to the back surface of the first wiring structure, and fixed onto the back surface of the first wiring structure.

3. The wiring board according to claim 1, wherein the electronic component is arranged in the cavity that is formed by cutting off the reinforcing insulating layer up to a certain position that does not reach the back surface of the first wiring structure, and fixed onto the reinforcing insulating layer that forms a bottom surface of the cavity.

4. the wiring board according to claim 1, wherein
the second wiring structure includes a plurality of the electronic components that are respectively arranged in a plurality of the cavities that are formed by cutting off the reinforcing insulating layer in a direction toward the back surface of the first wiring structure, and
the filled resin layer is filled in the plurality of the cavities and covers the plurality of the electronic components.

5. The wiring board according to claim 1, wherein a thickness of the second wiring structure is equal to or larger than a thickness of the first wiring structure.

6. The wiring board according to claim 1, further comprising:
a support, wherein
the first wiring structure is formed on the support such that the mounting surface is oriented toward the support.

7. A laminated wiring board comprising:
a wiring board that is laminated on another wiring board, wherein
the wiring board includes:
a first wiring structure that includes a mounting surface for a semiconductor element and a back surface on an opposite side of the mounting surface; and
a second wiring structure that is formed on the back surface of the first wiring structure, wherein
the second wiring structure includes
a reinforcing insulating layer that is formed on the back surface of the first wiring structure,
a cavity that is formed by cutting off the reinforcing insulating layer in a direction toward the back surface of the first wiring structure;
an electronic component that is arranged in the cavity; and
a filled resin layer that is filled in the cavity and covers the electronic component.

8. The laminated wiring board according to claim 7, wherein
an electrode pad is provided on an opposite surface of the filled resin layer, the opposite surface located on an opposite side of the first wiring structure,
another electrode pad is provided on a surface of the other wiring board,
the electrode pad and the other electrode pad are electrically connected to each other, and
the wiring board is laminated on the other wiring board.
